(19) United States
(12) Patent Application Publication
(10) Pub. No.: US 2022/0344385 A1
(43) Pub. Date: Oct. 27, 2022

(54) PHOTOGRAPHIC SENSOR

(71) Applicant: STMicroelectronics (Crolles 2) SAS, Crolles (FR)

(72) Inventor: Francois GUYADER, Montbonnot (FR)

(73) Assignee: STMicroelectronics (Crolles 2) SAS, Crolles (FR)

(21) Appl. No.: 17/724,739

(22) Filed: Apr. 20, 2022

(30) Foreign Application Priority Data
Apr. 21, 2021 (FR) 2104163

(51) Int. Cl. H01L 27/146

(52) U.S. Cl. CPC H01L 27/1463; H01L 27/14605; H01L 27/14683

(57) ABSTRACT

A semiconductor substrate includes a matrix of photosites. Each photosite is delimited by an isolation trench including polycrystalline silicon. A peripheral zone extends directly around the matrix of photosites. The peripheral zone includes dummy photosites delimited by isolation trenches including polycrystalline silicon. A density of polycrystalline silicon in the peripheral zone is between a density of polycrystalline silicon at an edge of the matrix of photosites and a density of polycrystalline silicon around the peripheral zone.

### PRIORITY CLAIM

This application claims the priority benefit of French Application for Patent No. 2104163, filed on Apr. 21, 2021, the content of which is hereby incorporated by reference in its entirety to the maximum extent allowable by law.

### TECHNICAL FIELD

Implementations relate to photographic sensors and, in particular, to stacked-layer image sensors.

### BACKGROUND

The photographic sensors comprise a matrix of photosites. The photosites allow to convert an electromagnetic radiation (UV, visible or IR) into an analog electric signal.

The photosites are disposed in rows and columns in the matrix. The photosites of the matrix are generally separated from each other by capacitive isolation trenches (also known in the art as Capacitive Deep Trench Isolation (CDTI) trenches).

The matrix of photosites can undergo mechanical stresses during its manufacturing. In particular, during the manufacturing of the matrix of photosites, the CDTI trenches are filled by depositing a material made of amorphous silicon. This material made of amorphous silicon is transformed into polycrystalline silicon during high-temperature annealing. This transformation induces a contraction of the material which translates into a tensile mechanical stress.

These mechanical stresses can lead to deformations of the matrix of photosites. In particular, the mechanical stresses that the matrix of photosites undergoes can curve it in such a way as to form a hollow on the surface of the matrix of photosites.

The surface of the matrix of photosites is thus not flat but curved. Therefore, the execution of a method for mechanical-chemical polishing on the hollow surface of the matrix of photosites leaves residues on the surface of the matrix of photosites. These residues can short-circuit the photosites of the matrix of photosites.

Moreover, certain photographic sensors are arranged on several superimposed tiers. A first tier having a free face comprises the matrix of photosites. A second tier disposed under the first tier, that is to say opposite to the free face of the first tier, comprises circuits for processing the signals generated by the matrix of photosites. The photographic sensor can comprise other tiers under the second tier.

The first tier can be assembled to the second tier by a method for direct gluing (without adhesive) which is a method for molecular gluing followed by thermal annealing for consolidation of the oxide-oxide gluing interface.

In particular, the face of the first tier opposite to its free face is assembled to the second tier. This face of the first tier opposite to its free face can have a hollow at the matrix of photosites.

When the matrix of photosites is hollow, the assembly between the first tier and the second tier can have lower performance.

In particular, the assembly between the first tier and the second tier can have bonding voids at the matrix of photosites. These bonding voids can lead to a rupture of the assembly during thinning methods which follow the gluing of the two tiers, or after an electric discontinuity between the two tiers.

These bonding voids result in particular from the curvature of the matrix of photosites at the edges of the matrix of photosites. The greater the curvature of the matrix of photosites, the larger the bonding voids.

It has been noted that the curvature of the matrix of photosites results from a sudden change in density of silicon between the matrix of photosites and the semiconductor substrate that surrounds it.

Thus, with such a matrix of photosites, the topology of the first tier is not adapted to obtain a satisfactory assembly between the first tier and the second tier.

There is therefore a need to propose a solution allowing to reduce the curvature of the matrix of photosites.

### SUMMARY

According to one aspect, a sensor is proposed comprising a semiconductor plate including a semiconductor substrate including: a matrix of photosites, each photosite being delimited by an isolation trench; and a peripheral zone extending directly around the matrix of photosites, the peripheral zone having a density of polycrystalline silicon between a density of polycrystalline silicon at the edge of the matrix of photosites and a density of polycrystalline silicon around the peripheral zone.

The peripheral zone allows to progressively decrease the density of polycrystalline silicon starting from the matrix of photosites.

Therefore, the mechanical stresses decrease progressively starting from the matrix of photosites.

Thus, the peripheral zone allows to reduce the curvature at the edge of the matrix of photosites.

Such a semiconductor plate can form a tier of a back-illuminated multi-tier photographic sensor. In particular, the semiconductor plate can thus be glued to another plate of the semiconductor substrate.

In an advantageous implementation, the peripheral zone comprises an isolation trench around the matrix of photosites, the isolation trench of the peripheral zone being spaced apart from the matrix of photosites by a distance greater than a width of the photosites.

Such a peripheral zone allows to progressively reduce the density of polycrystalline silicon around the matrix of photosites.

Advantageously, the peripheral zone comprises a set of dummy photosites formed in the substrate and delimited from each other by isolation trenches. The dummy photosites thus have a width greater than the width of the photosites of the matrix of photosites.

Preferably, the peripheral zone comprises a succession of isolation trenches extending around the matrix, the distance between two successive isolation trenches of the succession of isolation trenches being greater than the width of the photosites, this distance between the isolation trenches being increasing starting from the trench closest to the matrix of photosites.

Alternatively, the peripheral zone comprises an isolation trench around the matrix of photosites, the isolation trench of the peripheral zone extending over a depth smaller than a depth of the isolation trenches delimiting the photosites.

Such a peripheral zone also allows to progressively reduce the density of polycrystalline silicon around the matrix of photosites.

Advantageously, the peripheral zone comprises a set of dummy photosites formed in the substrate and delimited from each other by isolation trenches. The isolation trenches of the peripheral zone thus extend over a depth smaller than the depth of the isolation trenches delimiting the photosites of the matrix of photosites.

Preferably, the peripheral zone comprises a succession of isolation trenches extending around the matrix, the depth of these isolation trenches and the width of these isolation trenches being decreasing starting from the isolation trench closest to the matrix of photosites.

Advantageously, the isolation trenches of the peripheral zone have a depth between one third and two thirds of the depth of the isolation trenches delimiting the photosites of the matrix of photosites.

Preferably, the peripheral zone has a width of between 20 μm and 400 μm.

According to another aspect, a method for manufacturing a sensor is proposed, comprising: obtaining a semiconductor plate including a semiconductor substrate; forming a matrix of photosites in the semiconductor substrate, each photosite being delimited by an isolation trench; and forming a peripheral zone in the semiconductor substrate, the peripheral zone having a density of polycrystalline silicon between a density of polycrystalline silicon at the edge of the matrix of photosites and a density of polycrystalline silicon around the peripheral zone.

In an advantageous embodiment, the formation of the peripheral zone comprises a formation of an isolation trench around the matrix of photosites, the isolation trench of the peripheral zone being spaced apart from the matrix of photosites by a distance greater than a width of the photosites.

Preferably, the formation of said peripheral zone comprises a formation of a succession of isolation trenches extending around the matrix, the distance between two successive isolation trenches of the succession of isolation trenches being greater than the width of the photosites, this distance between the isolation trenches being increasing starting from the trench closest to the matrix of photosites.

Alternatively, the formation of the peripheral zone comprises a formation of an isolation trench around the matrix of photosites, the isolation trench of the peripheral zone extending over a depth smaller than a depth of the isolation trenches delimiting the photosites.

Preferably, the formation of said peripheral zone comprises a formation of a succession of isolation trenches extending around the matrix, the depth of these isolation trenches and the width of these isolation trenches being decreasing starting from the isolation trench closest to the matrix of photosites.

Advantageously, the isolation trenches of the peripheral zone are made in such a way that they have a depth between one third and two thirds of the depth of the isolation trenches delimiting the photosites of the matrix of photosites.

Preferably, the peripheral zone has a width of between 20 μm and 400 μm.

### BRIEF DESCRIPTION OF THE DRAWINGS

Other advantages and features of the invention will appear upon examination of the detailed description of embodiments and implementations, in no way limiting, and of the appended drawings, in which:

FIG. 1 illustrates a top view of a semiconductor plate of a sensor;

FIG. 2 illustrates a cross-sectional view of the semiconductor plate shown in FIG. 1;

FIG. 3 illustrates a cross-sectional view of a second implementation of a semiconductor plate; and

FIG. 4 illustrates an embodiment of a method for manufacturing a sensor.

### DETAILED DESCRIPTION

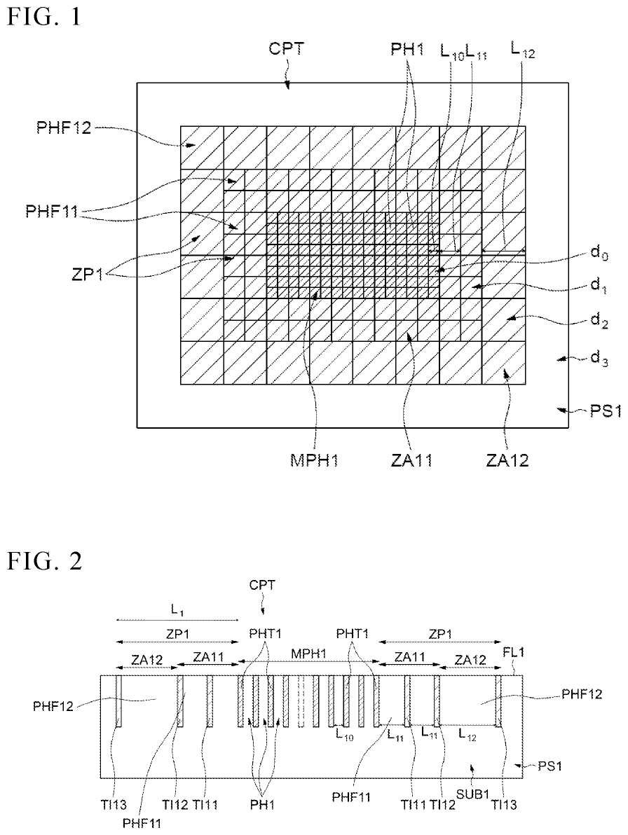

FIG. 1 illustrates a top view of a semiconductor plate PS1 of a sensor CPT according to one implementation. FIG. 2 illustrates a cross-sectional view of this semiconductor plate PS1.

The semiconductor plate PS1 comprises a semiconductor substrate SUB1 including a matrix of photosites MPH1. The photosites PH1 of the matrix MPH1 are disposed in rows and columns.

The photosites PH1 of the matrix MPH1 are isolated from each other by isolation trenches PHT1, preferably these isolation trenches PHT1 are capacitive isolation trenches (also known in the art as Capacitive Deep Trench Isolation (CDTI) trenches). The contour of the matrix MPH1 thus comprises an isolation trench PHT1. The isolation trenches PHT1 extend in depth in the semiconductor substrate SUB1 from a free face FL1 of the semiconductor substrate SUB1. For example, the isolation trenches PHT1 extend over a depth of between 3 μm and 10 μm.

The photosites PH1 have a width L₁₀ of between 0.5 μm and 5 μm. The width of a photosite is defined by the distance between two opposite isolation trenches PHT1 delimiting the photosite PH1.

The matrix of photosites MPH1 has a given pitch. This pitch is defined by the sum of the width of a photosite PH1 and the width of an isolation trench PHT1 that delimits this photosite PH1.

The semiconductor plate PS1 also comprises a peripheral zone ZP1 around the matrix of photosites. The peripheral zone ZP1 is thus formed in the semiconductor substrate SUB1. A region of the semiconductor substrate SUB1 further surrounds the peripheral zone ZP1.

In particular, in FIG. 1, the peripheral zone ZP1 comprises two annular zones ZA11, ZA12.

The peripheral zone ZP1 has a width L₁of between 20 μm and 400 μm.

A first annular zone ZA11 comprises two (peripheral) isolation trenches TII11, TI12. The first annular zone can comprise dummy photosites PHF11 between the two isolation trenches TI11, TI12 and between the isolation trench TI11 and the matrix of photosites. In this context, a “dummy photosite” may, for example, have a same composition, configuration and general layout as the photosite PH1, with the exception that no electrical connection is made to dummy photosite. Alternatively, the “dummy photosite” may, for example, just comprise a portion of the substrate delimited by (peripheral) isolation trenches.

A first isolation trench TI11 extends around the matrix of photosites MPH1.

A second isolation trench TI12 extends around the first isolation trench TI11.

The first isolation trench TI11 is located at a distance L₁₁ greater than the width L₁₀ of a photosite PH1 from the matrix of photosites MPH1.

Likewise, the second isolation trench TI12 is located at a distance greater than the width of a photosite PH1. This distance is equal to the distance between the first isolation trench TI11 and the matrix of photosites MPH1. These distances are for example between 1 μm and 10 μm.

The isolation trenches TI11, TI12 of the first annular zone are deep isolation trenches. The isolation trenches TI11, TI12 extend from the free face of the substrate SUB1 over a depth identical to that of the isolation trenches PHT1 delimiting the photosites PH1. The isolation trenches TI11, TI12 can be CDTI trenches. The isolation trenches TI11, TI12 are thus formed from a dielectric coating material such as silicon dioxide and filled with silicon. Alternatively, the isolation trenches TI11, TI12 can be deep isolation trenches (Deep Trench Isolation—DTI). The isolation trenches TI11, TI12 are thus filled only with a dielectric coating material, such as silicon dioxide.

The isolation trenches TI11, TI12 of the first annular zone ZA11 have the same width. The width of the isolation trenches TI11, TI12 of the first annular zone ZA11 is the same as the width of the isolation trenches PHT1 of the matrix of photosites MPH1.

Preferably, the first annular zone ZA11 has a pitch two times greater than the pitch of the matrix of photosites MPH1. The pitch of the first annular zone ZA11 is defined by the sum of the width of an isolation trench TI11, TI12 and the distance between two isolation trenches TI11, TI12.

The second annular zone ZA12 extends around the first annular zone ZA11. The second annular zone ZA12 comprises an isolation trench TI13. This isolation trench TI13 extends around the first annular zone ZA11. The second annular zone can comprise dummy photosites PHF12 formed in the substrate between the isolation trench TI13 and the isolation trench TI12.

The isolation trench TI13 of the second annular zone ZA12 is located, with respect to the first annular zone ZA11, at a distance L₁₂ greater than the distance L₁₁ between the two isolation trenches TI11, TI12 from the first annular zone ZA11. This distance is for example between 2 μm and 20 μm.

The isolation trench TI13 is a deep isolation trench. The isolation trench TI13 extends from the free face of the substrate over a depth identical to that of the isolation trenches PHT1 delimiting the photosites PH1. The isolation trench TI13 can be a CDTI trench. The isolation trench TI13 is thus formed from a dielectric coating material such as silicon dioxide and filled with silicon. Alternatively, the isolation trenches TI13 can be deep isolation trenches (Deep Trench Isolation). The isolation trench TI13 is thus filled only with a dielectric coating material, such as silicon dioxide.

The width of the isolation trench TI13 of the second annular zone ZA12 is identical to the width of the isolation trenches PHT1 of the matrix of photosites MPH1.

Preferably, the second annular zone ZA12 has a pitch four times greater than the pitch of the matrix of photosites MPH1. The pitch of the second annular zone ZA12 is defined by the sum of the width of the isolation trench TI13 and the distance between the isolation trench TI13 and the first annular zone ZA11.

Thus, the pitch of the various annular zones ZA11, ZA12 of the peripheral zone ZP1 is greater than the pitch of the matrix of photosites MPH1 and is increasing starting from the annular zone ZA11 closest to the matrix of photosites MPH1.

This allows to progressively decrease the density of polycrystalline silicon starting from the matrix of photosites MPH1. In particular, the greater the pitch, the lower the density of polycrystalline silicon.

Thus, the first annular zone ZA11 has a density di of polycrystalline silicon. The second annular zone ZA12 has a density d₂ of polycrystalline silicon. The density di of polycrystalline silicon of the first annular zone ZA11 is between a density do of polycrystalline silicon on the edge of the matrix of photosites and the density d₁ of polycrystalline silicon of the second annular zone ZA12. The density di of polycrystalline silicon of the second annular zone ZA12 is greater than a density d₃ of polycrystalline silicon in the region of the semiconductor substrate which surrounds the peripheral zone ZP1.

Therefore, the mechanical stresses progressively decrease starting from the matrix of photosites MPH1.

Thus, the peripheral zone ZP1 allows to reduce the curvature at the edge of the matrix of photosites.

Such a semiconductor plate PS1 can form a tier of a multi-tier photographic sensor. The semiconductor plate PS1 can thus be glued to another plate of semiconductor substrate.

Of course, this first implementation is capable of various alternatives and modifications that will appear to a person skilled in the art.

In particular, the second annular zone ZA12 can comprise several isolation trenches arranged according to the pitch of the second annular zone ZA12. These isolation trenches thus extend over the same depth as the isolation trench TI13.

Likewise, the first annular zone ZA11 can comprise more than two isolation trenches arranged according to the pitch of the first annular zone ZA11. The first annular zone ZA11 can also comprise a single isolation trench.

Moreover, the peripheral zone ZP1 can comprise more than two annular zones around the matrix of photosites. In this case, the annular zones comprise at least one isolation trench having a width identical to the isolation trenches delimiting the photosites. The annular zones have an increasing pitch starting from the matrix of photosites.

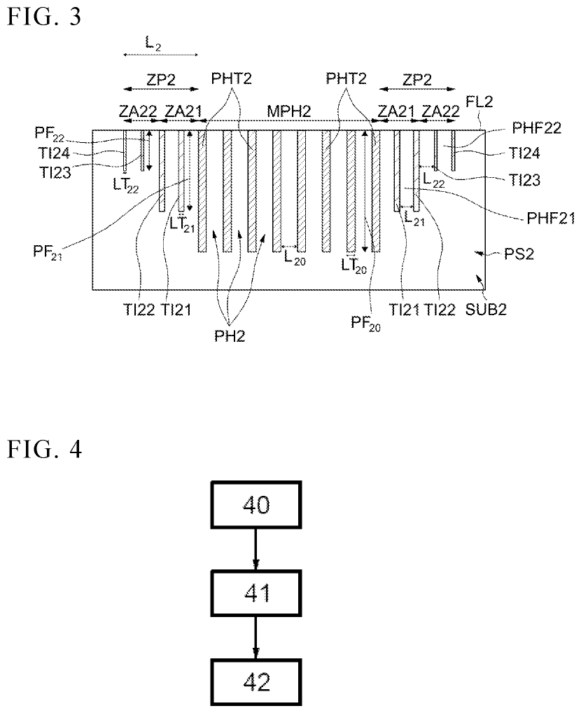

FIG. 3 illustrate a cross-sectional view of a second implementation of a semiconductor plate PS2.

The semiconductor plate PS2 comprises a semiconductor substrate SUB2 including a matrix of photosites MPH2. The photosites PH2 of the matrix MPH2 are disposed in rows and columns.

Like for FIG. 1, the photosites PH2 of the matrix MPH2 are isolated from each other by isolation trenches PHT2, preferably these isolation trenches PHT2 are capacitive isolation trenches (also known as Capacitive Deep Trench Isolation (CDTI) trenches). The contour of the matrix MPH2 thus comprises an isolation trench PHT2. The isolation trenches PHT2 extend in depth in the semiconductor substrate SUB2 from a free face FL2 of the substrate SUB2. For example, the isolation trenches PHT2 extend over a depth PF₂₀ of between 3 μm and 10 μm. Moreover, the isolation trenches PHT2 have for example a width of between 0.2 μm and 0.6 μm.

Like for FIG. 1, the photosites PH2 have a width L₂₀ of between 0.5 μm and 5 μm. The width of a photosite PH2 is defined by the distance between two opposite isolation trenches PHT2 delimiting the photosite PH2.

The semiconductor plate PS2 also comprises a peripheral zone ZP2 around the matrix of photosites MPH2. The peripheral zone ZP2 is thus formed in the semiconductor substrate SUB2.

In particular, the peripheral zone ZP2 comprises two annular zones ZA21, ZA22.

The peripheral zone ZP2 has a width L₂ of between 20 μm and 400 μm.

A first annular zone ZA21 comprises two isolation trenches TI21, TI22. The isolation trenches TI21, TI22 can be CDTI trenches. The isolation trenches TI21, TI22 are thus formed from a dielectric coating material such as silicon dioxide and filled with silicon. Alternatively, the isolation trenches TI21, TI22 can be deep isolation trenches (Deep Trench Isolation). The isolation trenches TI21, TI22 are thus filled only with a dielectric coating material, such as silicon dioxide.

A first isolation trench TI21 extends around the matrix of photosites MPH2.

A second isolation trench TI22 extends around the first isolation trench TI21.

The distance L₂₁ between the first isolation trench TI21 and the second isolation trench TI22 is identical to the width L₂₀ of a photosite PH2. Likewise, the distance between the first isolation trench TI21 and the matrix of photosites MPH2 is identical to the width of a photosite PH2.

The first annular zone ZA21 can comprise dummy photosites PHF21 formed in the substrate between the (peripheral) isolation trenches TI22 and TI21, as well as between the isolation trench TI21 and the matrix of photosites.

The isolation trenches TI21, TI22 of the first annular zone ZA21 have a width LT₂₁ smaller than the width LT₂₀ of the isolation trenches PHT2 delimiting the photosites PH2. For example, the isolation trenches TI21, TI22 of the first annular zone ZA21 have a width L₂₁ of between 0.1 μm and 0.3 μm.

Moreover, the isolation trenches TI21, TI22 of the first annular zone ZA21 extend less deeply than the isolation trenches PHT2 delimiting the photosites PH2. For example, the isolation trenches TI21, TI22 of the first annular zone ZA21 extend from the free face FL2 of the substrate SUB2 over a depth PF21 between one half and two thirds of the depth of the isolation trenches delimiting the photosites of the matrix of photosites.

The second annular zone ZA22 extends around the first annular zone ZA21. The second annular zone ZA22 comprises two isolation trenches TI23, TI24. These isolation trenches TI23, TI24 extend around the first annular zone ZA21. The isolation trenches TI23, TI24 can be CDTI trenches. The isolation trenches TI23, TI24 are thus formed from a dielectric coating material such as silicon dioxide and filled with silicon. Alternatively, the isolation trenches TI23, TI24 can be deep isolation trenches (Deep Trench Isolation). The isolation trenches TI23, TI24 are thus filled only with a dielectric coating material, such as silicon dioxide.

The distance L₂₂ between the two isolation trenches TI23, TI24 of the second annular zone ZA22 is equal to the width L₂₀ of a photosite PH2 of the matrix of photosites MPH2. Likewise, the first isolation trench TI23 of the second annular zone ZA22 is located at a distance from the first annular zone ZA21 equal to the width L₂₀ of a photosite PH2 of the matrix of photosites MPH2.

The second annular zone ZA22 can comprise dummy photosites PHF22 formed in the substrate between the isolation trenches TI24 and TI23, as well as between the isolation trenches TI23 and TI22.

The isolation trenches TI23, TI24 of the second annular zone ZA22 have a width LT22 smaller than the width LT21 of the isolation trenches TI21, TI22 of the first annular zone ZA21. For example, the isolation trenches TI23, TI24 of the second annular zone ZA22 have a width L₂₂ of between 0.05 μm and 0.15 μm.

Moreover, the isolation trenches TI23, TI24 of the second annular zone ZA22 extend less deeply than the isolation trenches TI21, TI22 of the first annular zone ZA22. For example, the isolation trenches TI23, TI24 of the second annular zone ZA22 extend from the free face FL2 of the substrate over a depth PF22 between one third and one half of the depth of the isolation trenches delimiting the photosites of the matrix of photosites.

Thus, the width and the depth of the isolation trenches TI21, TI22, TI23, TI24 of the various annular zones ZA21, ZA22 of the peripheral zone ZP2 are smaller than the width of the isolation trenches PHT2 of the matrix of photosites MPH2. Moreover, the width and the depth of the isolation trenches TI21, TI22, TI23, TI24 are decreasing starting from the annular zone ZA21 closest to the matrix of photosites MPH2.

Such a peripheral zone ZP2 also allows to progressively decrease the density of polycrystalline silicon starting from the matrix of photosites MPH2. In particular, the smaller the depth of the isolation trenches, the lower the density of polycrystalline silicon.

Therefore, the mechanical stresses progressively decrease starting from the matrix of photosites MPH2.

Thus, the peripheral zone ZP2 allows to reduce the curvature at the edge of the matrix of photosites MPH2.

Such a semiconductor plate PS2 can also form a tier of a multi-tier photographic sensor. The semiconductor plate can thus be glued to another plate of semiconductor substrate.

Of course, this second implementation is capable of various alternatives and modifications that will appear to a person skilled in the art.

In particular, the first annular zone ZA21 can comprise more than two isolation trenches having the same width and extending over the same depth. The first annular zone can also comprise a single isolation trench.

Likewise, the second annular zone ZA22 can comprise more than two isolation trenches having the same width and extending over the same depth. The second annular zone ZA22 can also comprise a single isolation trench.

Moreover, the peripheral zone ZP2 can comprise more than two annular zones around the matrix of photosites, or a single annular zone. In this case, the annular zones comprise at least one isolation trench. The width and the depth of the isolation trenches thus decrease between the various annular zones starting from the matrix of photosites. Moreover, the distance between the isolation trenches of the various annular zones remains identical to the width of the photosites of the matrix of photosites.

It is also possible to combine the first implementation of the semiconductor plate, illustrated for example in FIGS. 1 and 2, with the second implementation illustrated in FIG. 3. In this case, the annular zones of the peripheral zone have a pitch that is increasing starting from the annular zone closest to the matrix of photosites, and the isolation trenches of the annular zones of the peripheral zone have a width and a depth that are decreasing starting from the annular zone closest to the matrix of photosites.

FIG. 4 illustrates an embodiment of a method for manufacturing a sensor according to an implementation of the invention.

The method comprises a step 40 of obtaining in which a semiconductor plate including a semiconductor substrate is obtained. Such a semiconductor plate can be obtained by methods well known to a person skilled in the art.

The method further comprises a step 41 of forming a matrix of photosites in which a matrix of photosites is formed in the semiconductor substrate of the semiconductor plate. The matrix of photosites can be formed by methods well known to a person skilled in the art. In particular, the matrix of photosites is formed in such a way as to obtain several photosites arranged in rows and in columns, each photosite being separated by isolation trenches, in particular capacitive isolation trenches.

The method further comprises a step 42 of forming a peripheral zone. In this step, a peripheral zone is formed around the photosite matrix.

In particular, the formation of the peripheral zone comprises a formation of at least one annular zone including at least one isolation trench.

For example, the formation of the peripheral zone can comprise the formation of the annular zones illustrated in FIGS. 1 and 2, or the formation of the annular zones illustrated in FIG. 3.

The isolation trenches of the annular zones can be obtained by methods known to a person skilled in the art. For example, the isolation trenches of the annular zones can be obtained by etching then by deposition of a dielectric material, such as silicon dioxide.

1. A sensor, comprising:
a semiconductor substrate;
a matrix of photosites in the semiconductor substrate, each photosite of the matrix being delimited by an isolation trench including polycrystalline silicon; and
a peripheral zone of the semiconductor substrate extending directly around the matrix of photosites, the peripheral zone including dummy photosites delimited by isolation trenches including polycrystalline silicon;
wherein a density of polycrystalline silicon in the peripheral zone is less than a density of polycrystalline silicon at an outer edge of the matrix of photosites and greater than a density of polycrystalline silicon in a region of the semiconductor substrate around the peripheral zone.

2. The sensor according to claim 1, wherein the peripheral zone comprises a peripheral isolation trench around the matrix of photosites, the peripheral isolation trench of the peripheral zone being spaced apart from the outer edge of the matrix of photosites by a distance greater than a width of the photosites in the matrix.

3. The sensor according to claim 1, wherein the peripheral zone comprises a succession of peripheral isolation trenches extending around the matrix of photosites, wherein a distance between two successive peripheral isolation trenches of the succession of peripheral isolation trenches is greater than a width of the photosites in the matrix, and wherein said distance between the two successive peripheral isolation trenches increases starting from the peripheral isolation trench closest to the outer edge of the matrix of photosites.

4. The sensor according to claim 1, wherein the peripheral zone comprises a peripheral isolation trench around the matrix of photosites, the peripheral isolation trench of the peripheral zone extending over a depth smaller than a depth of the isolation trenches delimiting the photosites of the matrix.

5. The sensor according to claim 1, wherein the peripheral zone comprises a succession of peripheral isolation trenches extending around the matrix of photosites, wherein a depth of the peripheral isolation trenches and a width of the peripheral isolation trenches decreases starting from the peripheral isolation trench closest to the matrix of photosites.

6. The sensor according to claim 5, wherein the peripheral isolation trenches of the peripheral zone have the depth between one third and two thirds of a depth of the isolation trenches delimiting the photosites of the matrix.

7. The sensor according to claim 1, wherein the peripheral zone has a width of between 20 μm and 400 μm.

8. A method for manufacturing a sensor, comprising:
forming a matrix of photosites in a semiconductor substrate, each photosite being delimited by an isolation trench including polycrystalline silicon; and
forming a peripheral zone in the semiconductor substrate extending directly around the matrix of photosites, the peripheral zone including dummy photosites delimited by isolation trenches including polycrystalline silicon;
wherein a density of polycrystalline silicon in the peripheral zone is less than a density of polycrystalline silicon at an outer edge of the matrix of photosites and greater than a density of polycrystalline silicon in a region of the semiconductor substrate around the peripheral zone.

9. The method according to claim 8, wherein forming the peripheral zone comprises forming a peripheral isolation trench around the matrix of photosites, the peripheral isolation trench of the peripheral zone being spaced apart from the matrix of photosites by a distance greater than a width of the photosites.

10. The method according to claim 8, wherein forming said peripheral zone comprises forming a succession of peripheral isolation trenches extending around the matrix, wherein a distance between two successive peripheral isolation trenches of the succession of peripheral isolation trenches is greater than a width of the photosites, wherein a distance between the peripheral isolation trenches increases starting from the peripheral isolation trench closest to the matrix of photosites.

11. The method according to claim 8, wherein forming the peripheral zone comprises forming a peripheral isolation trench around the matrix of photosites, the peripheral isolation trench of the peripheral zone extending over a depth smaller than a depth of the isolation trenches delimiting the photosites.

12. The method according to claim 12, wherein forming said peripheral zone comprises forming a succession of peripheral isolation trenches extending around the matrix, wherein a depth of the peripheral isolation trenches and a width of the peripheral isolation trenches decreases starting from the peripheral isolation trench closest to the matrix of photosites.

13. The method according to claim 12, wherein the peripheral isolation trenches of the peripheral zone are made in such a way that they have a depth between one third and two thirds of the depth of the isolation trenches delimiting the photosites of the matrix.

14. The method according to claim 8, wherein the peripheral zone has a width of between 20 μm and 400 μm.

15. A sensor, comprising:
a semiconductor substrate;
a matrix of photosites in the semiconductor substrate delimited by first isolation trenches including polycrystalline silicon; and
a first peripheral zone of the semiconductor substrate surrounding the matrix of photosites, the first peripheral zone including first dummy photosites delimited by second isolation trenches including polycrystalline silicon;
wherein a density of polycrystalline silicon in the second isolation trenches of the first peripheral zone is less than a density of polycrystalline silicon in the first isolation trenches for the matrix of photosites.

16. The sensor of claim 15, further comprising:
a second peripheral zone of the semiconductor substrate surrounding the first peripheral zone of the semiconductor substrate, the second peripheral zone including second dummy photosites delimited by third isolation trenches including polycrystalline silicon;
wherein a density of polycrystalline silicon in the third isolation trenches of the second peripheral zone is less than the density of polycrystalline silicon in the second isolation trenches of the first peripheral zone.

17. The sensor of claim 16, wherein the matrix of photosites are arranged with a first pitch, the first dummy photosites are arranged with a second pitch greater than the first pitch, and the second dummy photosites are arranged with a third pitch greater than the second pitch.

18. The sensor of claim 17, wherein the second pitch is two times the first pitch and the third pitch is four times the first pitch.

19. The sensor of claim 16, wherein a depth of the second isolation trenches is less than a depth of the first isolation trenches and wherein a depth of the third isolation trenches is less than the depth of the second isolation trenches.

20. The sensor of claim 15, wherein the matrix of photosites are arranged with a first pitch and the first dummy photosites are arranged with a second pitch greater than the first pitch.

21. The sensor of claim 20, wherein the second pitch is two times the first pitch.

22. The sensor of claim 15, wherein a depth of the second isolation trenches is less than a depth of the first isolation trenches.
